(19) United States
(12) Patent Application Publication
(10) Pub. No.: US 2026/0142263 A1
(43) Pub. Date: May 21, 2026

(54) BATTERY SYSTEM AND COOLING METHOD OF BATTERY PACK

(71) Applicant: TOYOTA JIDOSHA KABUSHIKI KAISHA, Toyota-shi (JP)

(72) Inventor: Yohei TAKAHASHI, Toyota-shi (JP)

(73) Assignee: TOYOTA JIDOSHA KABUSHIKI KAISHA, Toyota-shi (JP)

(21) Appl. No.: 19/293,401

(22) Filed: Aug. 7, 2025

(30) Foreign Application Priority Data
Nov. 18, 2024 (JP) 2024-200977

(51) Int. Cl. H01M 10/633; B60L 58/26; F04D 27/00; G01K 1/02; G01R 31/3842; G01R 31/389; G01R 31/396; H01M 10/48; H01M 10/613; H01M 10/625; H01M 10/6563

(52) U.S. Cl. CPC H01M 10/633; B60L 58/26; F04D 27/00; G01K 1/026; G01R 31/3842; G01R 31/389; G01R 31/396; H01M 10/482; H01M 10/486; H01M 10/613; H01M 10/625; H01M 10/6563; B60L 2240/12; B60L 2240/547; B60L 2240/549; B60L 2240/662; H01M 2220/20

(57) ABSTRACT

A battery system includes a battery pack including a plurality of battery cells, a voltage sensor that detects a voltage of each of the battery cells, a current sensor that detects a current flowing through each of the battery cells, a fan that cools the battery pack by feeding air to the battery pack, and a control device for controlling air volume of the fan so as to match a target air volume. The control device calculates internal resistance of each of the battery cells based on detection values of the voltage sensor and the current sensor. When the internal resistance of any one battery cell of the battery cells exceeds a threshold value, the control device increases the target air volume as compared with when the internal resistances of the battery cells are all lower than the threshold value.

### CROSS-REFERENCE TO RELATED APPLICATION

This application claims priority to Japanese Patent Application No. 2024-200977 filed on Nov. 18, 2024. The disclosure of the above-identified application, including the specification, drawings, and claims, is incorporated by reference herein in its entirety.

### BACKGROUND

### 1. Technical Field

The present disclosure relates to a battery system and a cooling method of a battery pack.

### 2. Description of Related Art

Japanese Unexamined Patent Application Publication No. 2013-69470 (JP 2013-69470 A) discloses a battery cooling device that cools a battery that is installed in an electrified vehicle, using a fan. Taking into account decrease in cooling capacity of the fan due to deterioration over time, in JP 2013-69470 A, a correction coefficient is learned for each control cycle, such that an estimated temperature of the battery that is calculated from the cooling capacity of the fan and the amount of heat generated by the battery, matches a detected temperature of the battery that is detected by a temperature sensor. When the correction coefficient is smaller than 1.0, determination is made that the actual cooling capacity is decreasing, and a target rotation speed of the fan is increased to increase the cooling capacity.

### SUMMARY

An electrified vehicle is equipped with a battery pack that includes a plurality of battery cells that is connected in series. In order to protect the battery pack from abnormalities (including deterioration and/or failure) caused by temperature rise in the battery pack, controlling air volume of a fan using internal temperature of each of the battery cells is desirable. The internal temperature of the battery cell is dependent on the amount of heat generated in the battery cell. The amount of heat generated in a battery cell is determined by the product of the square of an electric current flowing through the battery cell and internal resistance thereof. Accordingly, as the internal resistance increases due to deterioration of the battery cell progressing, the amount of heat generated by the battery cell increases.

In JP 2013-69470 A, the temperature outside a battery case of the battery is detected by the temperature sensor, and the target rotation speed of the fan is decided from the detected temperature of the battery and the current vehicle speed, and this target rotation speed is corrected using the correction coefficient that is described above. However, the detected temperature that is detected by the temperature sensor is the external temperature of the battery, and is easily affected by the surrounding environment of the battery. Accordingly, there is a concern that a discrepancy may occur between the cooling capacity that is required to cool each of the battery cells of the battery pack and the cooling capacity of the fan. When the cooling capacity of the fan is not sufficient to satisfy the cooling capacity that is required by the battery cells, there is a possibility that the battery cells will overheat. On the other hand, when the cooling capacity of the fan exceeds the cooling capacity that is required by the battery cells, there is a possibility that the electric power consumption of the fan, and noise due to operation of the fan, will unnecessarily increase.

The present disclosure has been made to solve the above problems, and an object of the present disclosure is to cool a battery pack with an appropriate cooling capacity, in accordance with the amount of heat generated by battery cells.

(1) A battery system according to an aspect of the present disclosure includes a battery pack including a plurality of battery cells, a voltage sensor that detects a voltage of each of the battery cells, a current sensor that detects a current flowing through each of the battery cells, a fan that cools the battery pack by feeding air to the battery pack, and a control device for controlling an air volume of the fan so as to match a target air volume. The control device calculates an internal resistance of each of the battery cells, based on detection values of the voltage sensor and the current sensor. The control device increases the target air volume as compared with when the internal resistances of the battery cells are all lower than a threshold value, when the internal resistance of any one battery cell of the battery cells exceeds the threshold value.

According to the above configuration (1), the amount of heat generated by each of the battery cells making up the battery pack can be estimated by calculating the internal resistance of each of the battery cells. This enables controlling the air volume of the fan to an adequate air volume in accordance with the amount of heat generated by each of the battery cells. Accordingly, generation of unnecessary noise and electric power consumption can be reduced while protecting the battery pack from overheating.

(2) The battery pack is configured to store electric power for driving an electrified vehicle. The battery system further includes a temperature sensor for detecting an external temperature of at least one battery cell of the battery cells, and a vehicle speed sensor for detecting a vehicle speed of the electrified vehicle. The control device decides the target air volume based on detection values of the temperature sensor and the vehicle speed sensor, when the internal resistances of the battery cells are all lower than the threshold value. The control device increases the target air volume as compared with the target air volume that is decided based on the detection values of the temperature sensor and the vehicle speed sensor, when the internal resistance of any one battery cell of the battery cells exceeds the threshold value.

According to the above configuration (2), generation of unnecessary noise and electric power consumption can be reduced while protecting the battery pack from overheating, in the electrified vehicle that is driven using electric power from the battery pack, as well.

(3) A plurality of modes are set regarding the fan, in which a relation between the vehicle speed of the electrified vehicle and the target air volume is different from one another. The fan is configured to switch operation modes among the modes. When the internal resistance of any one battery cell of the battery cells exceeds the threshold value, the control device increases the target air volume for the same vehicle speed in at least one mode of the modes, as compared with when the internal resistances of the battery cells are all lower than the threshold value.

According to the above configuration (3), the cooling capacity of the fan can be increased in response to the amount of heat generated by the battery cells of which the internal resistance has increased due to deterioration, thereby appropriately protecting the battery pack from overheating.

(4) A plurality of modes are set regarding the fan, in which a relation between the vehicle speed of the electrified vehicle and the target air volume is different from one another. The fan is configured to switch operation modes among the modes. The control device is configured to switch the operation mode of the fan from a first mode to a second mode in which the target air volume for the same vehicle speed is greater, in response to the detection value of the temperature sensor reaching a switching temperature. The control device lowers the switching temperature when the internal resistance of any one battery cell of the battery cells exceeds the threshold value, as compared with when the internal resistances of the battery cells are all lower than the threshold value.

According to the above configuration (4), the cooling capacity of the fan can be increased in accordance with the amount of heat generated by the battery cell of which internal resistance has increased due to deterioration, thereby appropriately protecting the battery pack from overheating.

(5) A cooling method for a battery pack according to another aspect of the present disclosure is a cooling method for cooling a battery pack including a plurality of battery cells. The battery pack is configured to store electric power for driving an electrified vehicle. The battery pack includes a voltage sensor that detects a voltage of each of the battery cells, a current sensor that detects a current flowing through each of the battery cells, a fan that cools the battery pack by feeding air to the battery pack, and a temperature sensor for detecting an external temperature of at least one battery cell of the battery cells. The electrified vehicle is provided with a vehicle speed sensor that detects a vehicle speed of the electrified vehicle. The cooling method includes calculating an internal resistance of each of the battery cells based on detection values of the voltage sensor and the current sensor, deciding a target air volume of the fan based on detection values of the temperature sensor and the vehicle speed sensor when the internal resistances of the battery cells are all lower than a threshold value, increasing the target air volume as compared with the target air volume that is decided based on the detection values of the temperature sensor and the vehicle speed sensor, when the internal resistance of any one battery cell of the battery cells exceeds the threshold value, and controlling an air volume of the fan so as to match the target air volume.

According to the above cooling method (5), the air volume of the fan can be controlled to an adequate air volume in accordance with the amount of heat generated by each of the battery cells, in the same way as the above configuration (1).

According to the present disclosure, the battery pack can be cooled with an appropriate cooling capacity in accordance with the amount of heat generated by the battery cells.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a diagram illustrating a schematic overall configuration of an electrified vehicle that is equipped with a battery system according to an embodiment;

FIG. 2 is a diagram for describing a calculation technique for internal resistance of a battery cell;

FIG. 3 is a diagram for describing the calculation technique for internal resistance of the battery cell;

FIG. 4 is a diagram showing an example of a map;

FIG. 5 is a diagram showing processing that is executed by an ECU;

FIG. 6 is a flowchart showing processing procedures for air volume control of a fan according to the embodiment;

FIG. 7 is a diagram showing a modification of the processing that is executed by the ECU; and

FIG. 8 is a flowchart showing processing procedures for air volume control of the fan according to the modification of the embodiment.

### DETAILED DESCRIPTION OF EMBODIMENTS

An embodiment of the present disclosure will be described in detail below with reference to the drawings. Note that the same or corresponding portions are denoted by the same signs throughout the drawings, and description thereof will not be repeated.

### Overall Configuration of Electrified Vehicle

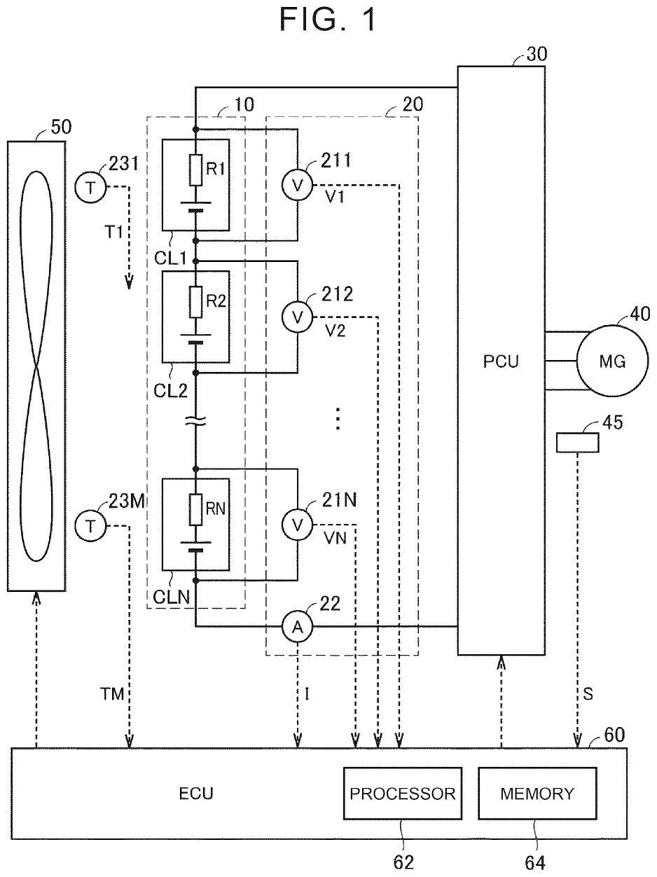

FIG. 1 is a diagram illustrating a schematic overall configuration of an electrified vehicle that is equipped with a battery system according to the present embodiment. In the example of FIG. 1, the electrified vehicle 100 is a battery electric vehicle. The electrified vehicle 100 may be a hybrid electric vehicle, a plug-in hybrid electric vehicle, a fuel cell electric vehicle, or the like.

The electrified vehicle 100 includes a battery pack 10, a monitoring unit 20, a power control unit (PCU) 30, a motor generator 40, a vehicle speed sensor 45, a fan 50, and an electronic control unit (ECU) 60.

The battery pack 10 includes N battery cells (single cells) CL1 to CLN. There is no particular limitation regarding N, so long as it is an integer of 2 or more, but it typically is a count of a dozen or so to several dozen. Hereinafter, the battery cells CL1 to CLN may be individually or collectively referred to as “battery cell(s) CL”.

Each of the battery cells CL is a rechargeable secondary battery such as a lithium-ion battery, a nickel metal hydride battery, or the like. In FIG. 1, N battery cells CL1 to CLN are connected in series, but the battery pack 10 may be configured by combining N battery cells CL1 to CLN in series and/or in parallel.

The battery pack 10 stores electric power for driving the motor generator 40. The battery pack 10 supplies electric power to the motor generator 40 through the PCU 30. Also, when the motor generator 40 performs power generation, the battery pack 10 receives generated electric power through the PCU 30, and is thus charged.

The monitoring unit 20 is a device for monitoring a state of the battery pack 10. The monitoring unit 20 includes N voltage sensors 211 to 21N, a current sensor 22, and M temperature sensors 231 to 23M.

The N voltage sensors 211 to 21N are provided corresponding to the N battery cells CL1 to CLN, respectively. Hereinafter, the voltage sensors 211 to 21N may be individually or collectively referred to as “voltage sensor(s) 21”. Each of the voltage sensors 21 detects voltage V of the corresponding battery cell CL, and outputs a signal indicating a detected value thereof to the ECU 60. The voltage sensor 211 detects voltage V1 of the battery cell CL1. The voltage sensor 212 detects voltage V2 of the battery cell CL2. The same applies to the other voltage sensors 213 to 21N.

The current sensor 22 detects current I input/output to/from the battery pack 10 (i.e., current I that flows in common through battery cells CL1 to CLN), and outputs a signal indicating a detected value thereof to the ECU 60. The current sensor 22 is a sensor for detecting the current I flowing through each of the battery cells CL. Accordingly, when the battery pack 10 is made up by connecting a plurality of serially connected battery cell groups in parallel, the monitoring unit 20 includes current sensors 22 of a number corresponding to the number of the parallel connected battery cell groups.

The M temperature sensors 231 to 23M are provided corresponding to the M battery cells CL out of the N battery cells CL1 to CLN, respectively. M is an integer that is equal to or greater than 1 and less than N. That is to say, not all battery cells CL are provided with a temperature sensor. In the example of FIG. 1, the temperature sensor 231 detects temperature T1 of the battery cell CL1. The temperature sensor 23M detects temperature TN of the battery cell CLN. However, battery cells CL to which the temperature sensors are to be installed are not limited to the battery cells CL at both ends as in this example, and may be set as appropriate.

Note that the temperature detected by the temperature sensors 231 to 23M is the temperature outside of a battery case of at least one battery cell CL among the multiple battery cells CL1 to CLN (hereinafter referred to as “external temperature”).

The PCU 30 executes bidirectional power conversion between the battery pack 10 and the motor generator 40, in accordance with a control command from the ECU 60. The PCU 30 includes, for example, a converter that boosts direct current voltage of the battery pack 10 and an inverter (neither illustrated) that converts direct current electric power from the converter into alternating current electric power to drive the motor generator 40.

The motor generator 40 is an alternating current rotating electrical machine, for example a three-phase alternating current synchronous motor with permanent magnets that are embedded in a rotor. The motor generator 40 is driven by receiving supply of electric power from the battery pack 10. The driving force of the motor generator 40 is transmitted to drive wheels via a drive shaft that is omitted from illustration. Also, when the electrified vehicle 100 is braking or acceleration is decreasing on a downhill slope, the motor generator 40 operates as a generator to perform regenerative power generation. The electric power that is generated by the motor generator 40 is stored in the battery pack 10 via the PCU 30.

The vehicle speed sensor 45 detects speed S of the electrified vehicle 100 (hereinafter referred to as “vehicle speed”), and outputs a signal indicating a detected value thereof to the ECU 60. Note that instead of the vehicle speed sensor 45, a signal indicating a detection value of a wheel speed sensor that detects a rotation speed (wheel speed) of the drive wheels, omitted from illustration, may be output to the ECU 60, and the vehicle speed S may be calculated at the ECU 60 using the wheel speed. Alternatively, a signal indicating a detection value of a rotation speed sensor that detects rotation speed of the motor generator 40 may be output to ECU 60, and vehicle speed S may be calculated at the ECU 60 using the rotation speed.

The fan 50 cools the battery pack 10 by feeding air to the battery pack 10. The fan 50 is configured to draw in outside air and circulate the outside air that is drawn in through a refrigerant passage that is provided in the battery case that houses the battery pack 10, thereby exchanging heat with the battery pack 10, and thus cooling the battery pack 10. The air volume of the fan 50 (rotation speed of fan 50) is controlled by the ECU 60.

The ECU 60 includes a processor 62 such as a central processing unit (CPU) or the like, memory 64 such as read-only memory (ROM), random access memory (RAM), or the like, and an input/output port (omitted from illustration) for inputting and outputting various types of signals. The ECU 60 manages the battery pack 10 based on signals received from the monitoring unit 20, and programs and maps that are stored in the memory 64. Also, the ECU 60 estimates the amount of heat generated by each of the battery cells CL included in the battery pack 10 based on signals that are received from the monitoring unit 20, and controls the air volume of the fan 50 based on estimation results thereof. The ECU 60 corresponds to an embodiment of “control device”. The ECU 60 may be divided into a plurality of ECUs for individual functions.

### Calculating Internal Resistance

The ECU 60 calculates internal resistance of each of the battery cells CL1 to CLN. The internal resistances of the battery cells CL1 to CLN are denoted by R1 to RN, respectively. The calculation method for the internal resistance R of each of the battery cells CL is the same, and accordingly a calculation technique for the internal resistance R1 of the battery cell CL1 will be representatively described here.

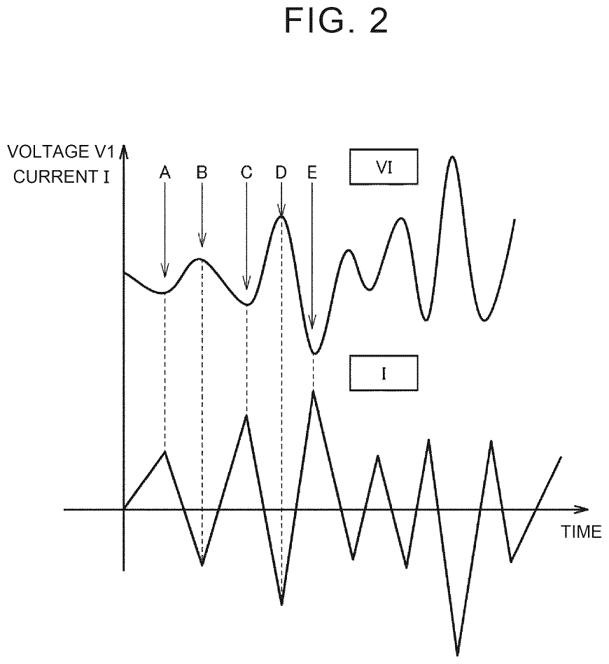

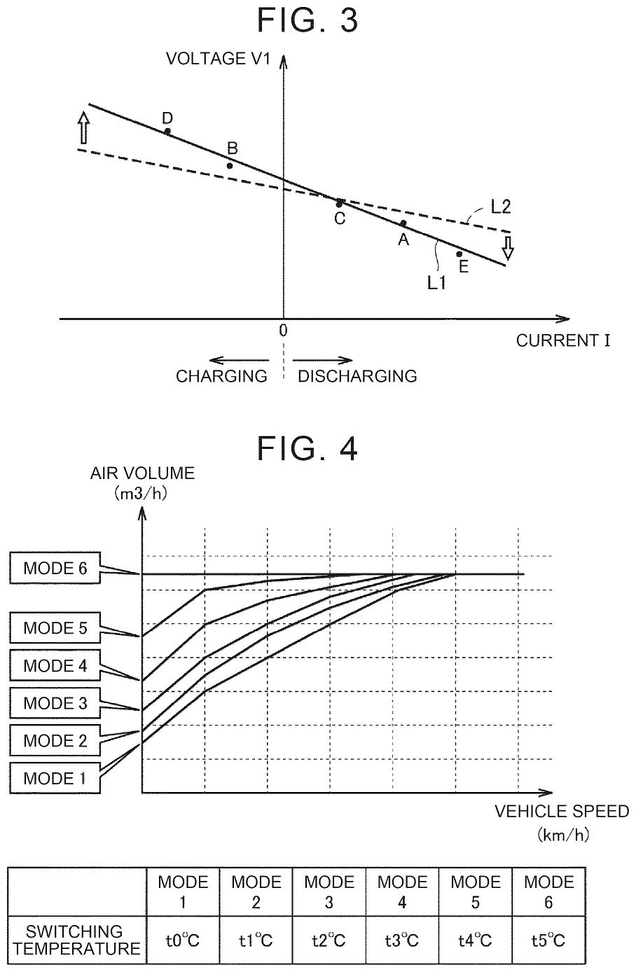

FIGS. 2 and 3 are diagrams for describing the calculation technique for the internal resistance R1 of the battery cell CL1. FIG. 2 is a diagram showing change over time in the voltage V1 of the battery cell CL1 and the current I input/output to/from the battery pack 10 (i.e., current flowing through battery cell CL1). The voltage V1 is the closed circuit voltage (CCV) of the battery cell CL1 that is detected by the voltage sensor 211. The sign of the current I is positive in a discharging direction of the battery pack 10, and is negative in a charging direction of the battery pack 10.

As shown in FIG. 2, the voltage V1 and the current I fluctuate as the battery pack 10 is repeatedly discharged and charged. When the current I is positive, the battery pack 10 is being discharged, and accordingly the voltage V1 decreases. When the current I is negative, the battery pack 10 is being charged, and accordingly the voltage V1 increases.

The ECU 60 acquires the voltage V1 and the current I at inflection points of a waveform of the voltage V1, and plots the values that are acquired on the I-V characteristics diagram shown in FIG. 3 (I-V plot). In FIG. 3, the voltage V1 and the current I are plotted at five inflection points A to E shown in FIG. 2.

The ECU 60 calculates a regression line L1 that indicates a relation between the voltage V1 and the current I by regression analysis (direct current regression computation) using the least squares method. The inclination of the regression line L1 represents the internal resistance R1 of the battery cell CL1. Carrying out the same for the other battery cells CL2 to CLN enables the internal resistances R2 to RN to be calculated.

As deterioration of the battery cell CL progresses, internal resistance R of the battery cell CL increases. A regression line L2 in FIG. 3 is a regression line that is calculated from the voltage V1 and the current I when the battery cell CL1 is in a brand new state. It can be seen that as the deterioration of the battery cell CL1 progresses, the inclination of the regression line becomes steeper, and the internal resistance R1 increases.

### Air Volume Control of Fan

As described with reference to FIG. 1, the temperature that is detected by the temperature sensors 231 to 23M is the external temperature of at least one battery cell CL among the battery cells CL1 to CLN. In order to protect the battery pack 10 from abnormalities (including deterioration and/or failure) caused by temperature rise in the battery pack 10, controlling the air volume of the fan 50 using the internal temperature of each of the battery cells CL is desirable.

Here, the internal temperature of the battery cell CL is dependent on the amount of heat generated in the battery cell CL. The amount of heat generated in the battery cell CL (amount of Joule heat generated) is determined by the product of the square of the current I and the internal resistance R (i.e., I²×R). That is to say, as the internal resistance R increases, the amount of heat generated increases, and the internal temperature of the battery cell CL rises.

In the example in FIG. 1, the current I flowing through the battery cells CL1 to CLN is a common current, and accordingly the amount of heat generated in the battery cell CL, which has a relatively great internal resistance R among the battery cells CL1 to CLN, is relatively great, and as a result, the internal temperature of that battery cell CL becomes relatively high. In order to appropriately protect the battery pack 10 from overheating, controlling the air volume of the fan 50 using the internal temperature of this battery cell CL is desirable.

The amount of heat generated by the battery cell CL can be estimated from the internal resistance R of that battery cell CL, and accordingly, in the present embodiment, the ECU 60 controls the air volume of the fan 50 (rotation speed of fan 50) based on the internal resistances R1 to RN of the battery cells CL1 to CLN that are calculated. Specifically, the ECU 60 calculates the internal resistances R1 to RN of the battery cells CL1 to CLN at each cycle that is set in advance, using the calculation technique described above, and compares the internal resistances R1 to RN that are calculated with a threshold value Rth. This threshold value Rth corresponds to a determination threshold value for determining deterioration of the battery cell CL. When the internal resistance R of the battery cell CL exceeds the threshold value Rth, the ECU 60 determines that the battery cell CL has deteriorated. When the internal resistance R of the battery cell CL is lower than the threshold value Rth, the ECU 60 determines that the battery cell CL is not deteriorated.

When the internal resistance R of any one battery cell CL of the battery cells CL1 to CLN exceeds the threshold value Rth, the ECU 60 increases the air volume of the fan 50 as compared with that when the internal resistances R of the battery cells CL are all lower than the threshold value Rth.

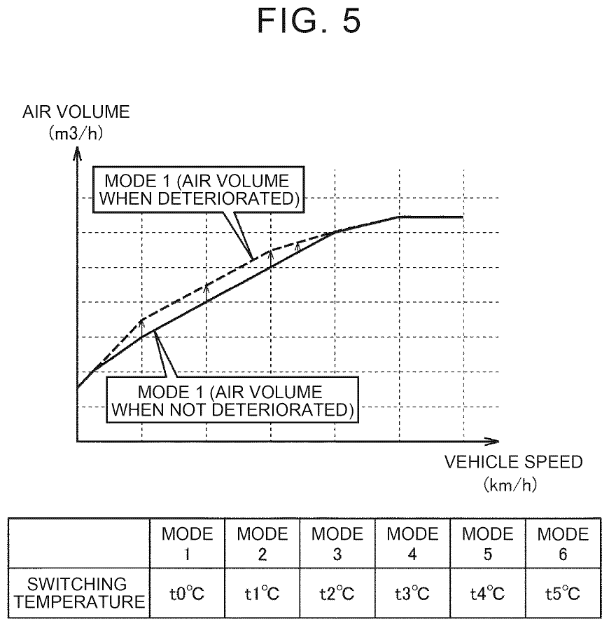

Specifically, the ECU 60 normally decides a target air volume of the fan 50 in accordance with the vehicle speed S that is detected by the vehicle speed sensor 45. A map that defines a relation between the vehicle speed S and the target air volume of the fan 50 is stored in the memory 64 of the ECU 60. FIG. 4 is a diagram showing an example of the map. The horizontal axis in FIG. 4 represents the vehicle speed (km/h) of the electrified vehicle 100, and the vertical axis represents the target air volume (m³/h) of the fan 50.

In this map, a plurality of types (e.g., six types) of graphs is set, each of which indicates a relation between the vehicle speed and the target air volume of the fan 50. These six types of graphs correspond to operation modes 1 to 6 of the fan 50, respectively. As shown in FIG. 4, the vehicle speed and the target air volume of the fan 50 have different relations with each other in the modes 1 to 6. Specifically, in modes 1 to 5, the target air volume is set such that the air volume increases as the vehicle speed increases. On the other hand, in mode 6, the target air volume is fixed to the greatest air volume that the fan 50 can feed, regardless of magnitude of the vehicle speed. Also, at the same vehicle speed, the target air volume is smallest in mode 1 and is greatest in mode 6. By switching from mode 1 to mode 2, mode 3, and so on through mode 6, in that order, the target air volume increases gradually.

The operation mode of the fan 50 is switched based on the external temperature of at least one of the battery cells CL detected by the temperature sensors 231 to 23M. FIG. 4 shows switching temperatures for switching the operation mode of the fan 50. For each mode, the switching temperature is set as a criterion for determining whether to switch to that mode. A relation of t0<t1<t2<t3<t4<t5 is satisfied among the switching temperatures t0 to t5 of the modes 1 to 6.

The ECU 60 switches the operation mode of the fan 50 to mode 1 when the detected temperatures that are detected by the temperature sensors 231 to 23M are equal to or lower than the mode 1 switching temperature, which is t0° C. When the detected temperatures that are detected by the temperature sensors 231 to 23M reach the mode 2 switching temperature, which is t1°C., while mode 1 is being executed, the ECU 60 then switches the operation mode of the fan 50 from mode 1 to mode 2. By switching from mode 1 to mode 2, the target air volume of the fan 50 increases for the same vehicle speed.

When the detected temperatures that are detected by the temperature sensors 231 to 23M reach the mode 3 switching temperature, which is t2°C, while mode 2 is being executed, the ECU 60 switches the operation mode of the fan 50 from mode 2 to mode 3. By switching from mode 2 to mode 3, the target air volume of the fan 50 further increases for the same vehicle speed.

In this way, the ECU 60 switches the operation mode of the fan 50 based on the external temperature of at least one of the battery cells CL that is detected by the temperature sensors 231 to 23M. Further, in each operation mode, the ECU 60 refers to the corresponding graph and decides the target air volume of the fan 50 from the current vehicle speed S of the electrified vehicle 100. The ECU 60 controls the rotation speed of the fan 50 such that the air volume of the fan 50 matches the target air volume.

In the above-described air volume control, when the internal resistance R of any one battery cell CL of the battery cells CL1 to CLN exceeds the threshold value Rth, the ECU 60 executes processing to increase the target air volume of the fan 50 for the current vehicle speed S. Specifically, the ECU 60 executes processing of changing a graph showing the relation between the vehicle speed and the target air volume of the fan 50 in each mode in the map shown in FIG. 4.

FIG. 5 is a diagram showing processing that is executed by the ECU 60. FIG. 5 shows a graph corresponding to mode 1, extracted from the map shown in FIG. 4. In FIG. 5, the solid line represents a graph showing the relation between the vehicle speed and the target air volume of the fan 50 in normal operations (when internal resistances R of battery cells CL are all lower than threshold value Rth). This graph is the same as the graph corresponding to mode 1 shown in FIG. 4. The dashed line represents a graph showing the relation between the vehicle speed and the target air volume of the fan 50 when the internal resistance R of any one battery cell CL of the battery cells CL1 to CLN exceeds the threshold value Rth.

As shown in FIG. 5, when the internal resistance R of any one battery cell CL of the battery cells CL1 to CLN exceeds the threshold value Rth, the target air volume is changed such that the target air volume for the same vehicle speed is greater as compared to that in normal operations. The size of the arrows in the drawing represents the amount of increase in the target air volume at each vehicle speed. The amount of increase in the target air volume at each vehicle speed may be the same or may differ for each vehicle speed. For example, the target air volume for each vehicle speed may be increased at a constant rate, as long as the target air volume does not exceed the maximum air volume of the fan 50.

The ECU 60 also changes the target air volume for the graphs corresponding to modes 2 to 5 in the same way as with the graph corresponding to mode 1, such that the air volume for the same vehicle speed becomes greater. Alternatively, a configuration may be made in which the target air volume of the graph corresponding to at least one mode from among modes 1 to 6 is changed.

### Flow of Processing

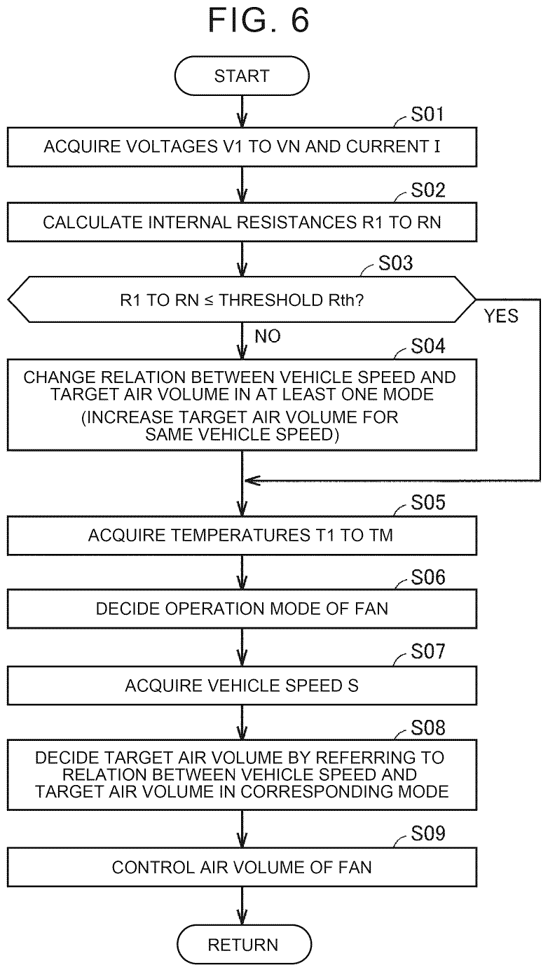

FIG. 6 is a flowchart showing processing procedures for air volume control of the fan 50 according to the present embodiment. This flowchart is executed every time a condition, set in advance, is satisfied (e.g., every control cycle). Each step is realized by software processing by the ECU 60, but may also be realized by hardware (electrical circuitry) disposed within the ECU 60. Hereinafter, the term “step” will be abbreviated to “S”.

In S01, the ECU 60 acquires the voltages V1 to VN from the voltage sensors 211 to 21N, and also acquires the current I from the current sensor 22, for a predetermined period of time.

In S02, the ECU 60 calculates the internal resistances R1 to RN based on the voltages V1 to VN and the current I that are acquired in S01. In S02, the calculation technique described with reference to FIGS. 2 and 3 can be used.

In S03, the ECU 60 compares the internal resistances R1 to RN with the threshold value Rth. When the internal resistances R1 to RN are all equal to or lower than the threshold value Rth (determination of YES in S03), the ECU 60 determines that none of the battery cells CL1 to CLN have deteriorated.

On the other hand, when any of the internal resistances R1 to RN exceeds the threshold value Rth (determination of NO in S03), the ECU 60 determines that one of the battery cells CL1 to CLN has deteriorated. In this case, in S04, the ECU 60 changes the relation between the vehicle speed and the target air volume in at least one mode of the operation modes of the fan 50. In S04, in a graph corresponding to at least one mode, the target air volume is changed as shown in FIG. 5, such that the target air volume for the same vehicle speed becomes greater as compared to that in the normal operations shown in FIG. 4. It should be noted that when determination is made that none of the battery cells CL1 to CLN have deteriorated, the processing of S04 is not performed.

In S05, the ECU 60 obtains the temperatures T1 to TM from the temperature sensors 231 to 23M.

In S06, the ECU 60 refers to the switching temperatures for each mode shown in the map in FIG. 4 and decides the operation mode of the fan 50 from the temperatures T1 to TM.

In S07, the ECU 60 acquires the vehicle speed S of the electrified vehicle 100 from the vehicle speed sensor 45.

In S08, the ECU 60 decides the target air volume of the fan 50 from the current vehicle speed S, by referring to a graph showing the relation between the vehicle speed and the target air volume in the corresponding mode, which is shown in the map of FIG. 4 or a map after changing.

In S09, the ECU 60 controls the rotation speed of the fan 50 such that the air volume of the fan 50 matches the target air volume.

As described above, when determination is made that any one battery cell CL of the battery cells CL1 to CLN has deteriorated, based on the internal resistances R1 to RN of the battery cells CL1 to CLN, the ECU 60 increases the target air volume of the fan 50 for the current vehicle speed S. This enables the cooling capacity of the fan 50 to be increased in response to the increase in the amount of heat generated in the battery cells CL that have deteriorated. Accordingly, the battery pack 10 can be appropriately protected from overheating.

Also, when determination is made that none of the battery cells CL have deteriorated, the ECU 60 does not perform the processing of increasing the target air volume described above, and decides the target air volume of the fan 50 in accordance with the external temperature of at least one battery cell CL and the current vehicle speed S. This enables the cooling capacity of the fan 50 to be suppressed from becoming excessive relative to the amount of heat generated by each of the battery cells CL.

It should be noted that when the rotation speed of the fan 50 is increased in order to increase the air volume from the fan 50, noise that is generated by the operation of the fan 50, and increase in the electric power consumption of the fan 50, become problematic. According to the present embodiment, the air volume of the fan 50 can be controlled to an adequate air volume in accordance with the amount of heat generated by each of the battery cells CL making up the battery pack 10. Accordingly, generation of unnecessary noise and electric power consumption can be reduced while suppressing overheating of the battery pack 10.

### Modifications

In the above-described embodiment, processing for increasing the target air volume of the fan 50 for the current vehicle speed S is described, in which a graph showing the relation between the vehicle speed and the target air volume of the fan 50 is changed in at least one mode among modes 1 to 6. The ECU 60 may execute processing of changing the switching temperature for switching the operation mode of the fan 50, instead of or in addition to this processing.

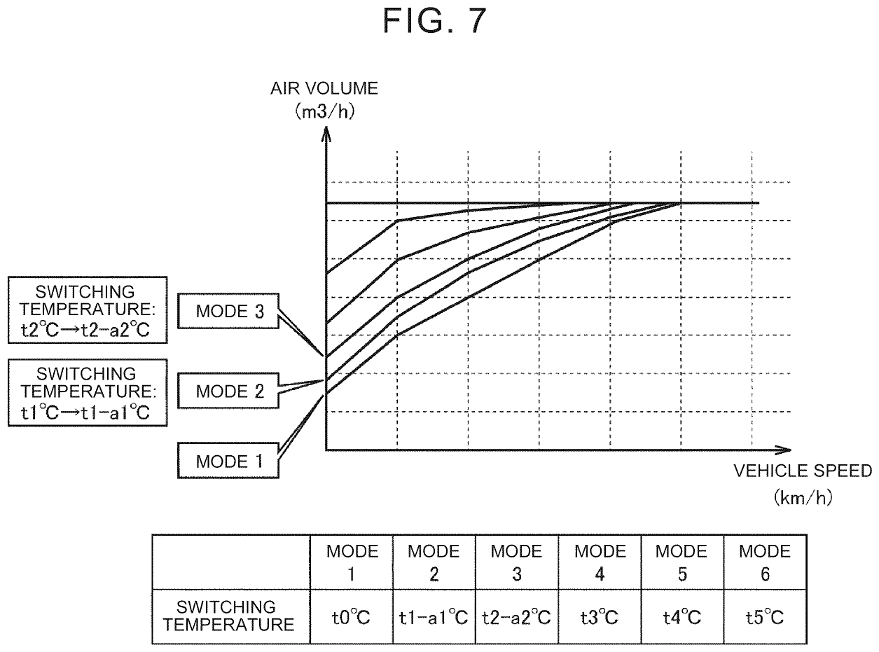

FIG. 7 is a diagram showing a modification of the processing that is executed by the ECU 60. FIG. 7 shows the same map as that shown in FIG. 4. FIG. 7 further shows the switching temperatures for switching the operation mode of the fan 50.

In the present modification, when the internal resistance R of any one battery cell CL of the battery cells CL1 to CLN exceeds the threshold value Rth, the ECU 60 executes processing of lowering the switching temperature for at least one mode among the modes 1 to 6. In the example of FIG. 7, the switching temperature for mode 2 is changed from t1°C. to t1−a1°C. Also, the switching temperature for mode 3 is changed from t2°C. to t2−a2°C. Note that the amount of decrease a1°C. of the switching temperature can be set as appropriate within a range that satisfies t0<t1−a1. The amount of decrease a2°C. of the switching temperature can be set as appropriate within a range that satisfies t1−a1<t2−a2.

According to the processing shown in FIG. 7, when the internal resistance R of any one battery cell CL of the battery cells CL1 to CLN exceeds the threshold value Rth, the ECU 60 switches the operation mode of the fan 50 from mode 1 to mode 2 in response to the detected temperature of the temperature sensors 231 to 23M reaching the switching temperature t1−a1°C. for mode 2 while mode 1 is being executed. That is to say, the operation mode of the fan 50 is switched from mode 1 to mode 2 at an earlier timing than in normal operations (when internal resistances R of battery cells CL are all lower than threshold value Rth). Also, by switching from mode 1 to mode 2, the target air volume of the fan 50 increases for the same vehicle speed.

Also, when the detected temperatures detected by the temperature sensors 231 to 23M reach the switching temperature t2−a2°C. for mode 2 while mode 2 is being executed, the ECU 60 switches the operation mode of the fan 50 from mode 2 to mode 3 in response thereto. That is to say, the operation mode of the fan 50 is switched from mode 2 to mode 3 at an earlier timing than in normal operations (when the internal resistances R of the battery cells CL are all lower than the threshold value Rth). Also, by switching from mode 2 to mode 3, the target air volume of the fan 50 further increases for the same vehicle speed.

### Flow of Processing

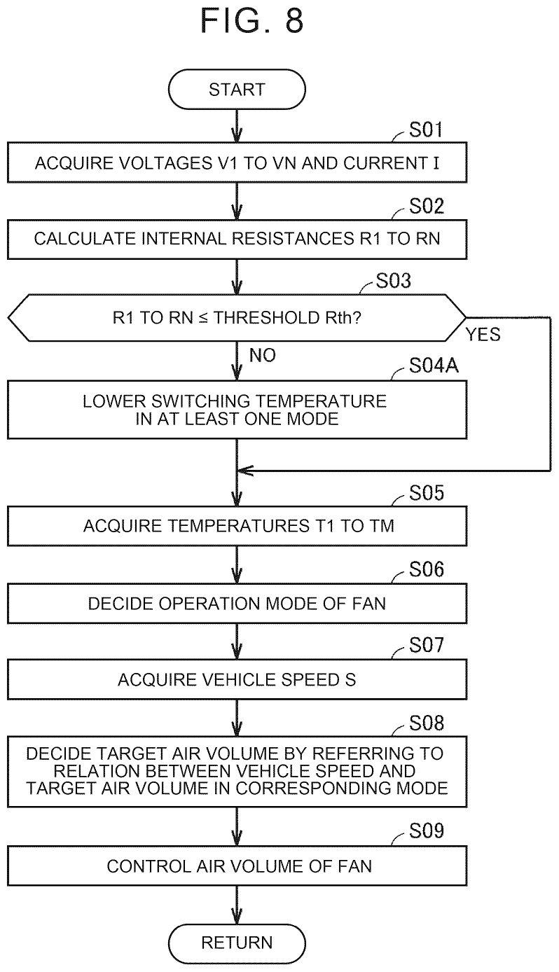

FIG. 8 is a flowchart showing processing procedures for air volume control of the fan 50 according to the present modification. The flowchart shown in FIG. 8 differs from the flowchart shown in FIG. 6 with respect to the point that S04 is replaced with S04A.

In the present modification, when any one of the internal resistances R1 to RN exceeds the threshold value Rth (determination of NO in S03), the ECU 60 lowers the switching temperature for at least one mode among the operation modes of the fan 50 in S04A. In S04A, the graph showing the relation between the vehicle speed and the target air volume of the fan 50 in each mode is not changed, as shown in FIG. 7, but the switching temperature for switching the mode is changed. It should be noted that when determination is made that none of the battery cells CL1 to CLN have deteriorated, the processing of S04A is not performed.

In the present modification, when determination is made that any one battery cell CL of the battery cells CL1 to CLN has deteriorated, the operation mode of the fan 50 is switched at an earlier timing in accordance with an increase in the detected temperature of the temperature sensors 231 to 23M, as compared with when determination is made that none of the battery cells CL has deteriorated. This switch in the operation mode increases the air volume of the fan 50 for the current vehicle speed S, and accordingly the cooling capacity of the fan 50 can be increased in accordance with the increase in the amount of heat generated in the battery cells CL that have deteriorated. Accordingly, the battery pack 10 can be appropriately protected from overheating.

Also, when determination is made that none of the battery cells CL have deteriorated, the processing of lowering the switching temperature described above is not performed, and the target air volume of the fan 50 is decided in accordance with the external temperature of at least one battery cell CL and the current vehicle speed S. This enables the cooling capacity of the fan 50 to be suppressed from becoming excessive relative to the amount of heat generated by each of the battery cells CL.

Thus, according to the present modification as well, generation of unnecessary noise and electric power consumption can be reduced while suppressing overheating of the battery pack 10.

The embodiment disclosed herein should be considered to be exemplary in all respects and not restrictive. The scope of the present disclosure is set forth in the claims rather than in the above description of the embodiment, and is intended to include all modifications within the meaning and scope equivalent to the claims.

What is claimed is:

1. A battery system comprising:
a battery pack including a plurality of battery cells;
a voltage sensor that detects a voltage of each of the battery cells;
a current sensor that detects a current flowing through each of the battery cells;
a fan that cools the battery pack by feeding air to the battery pack; and
a control device for controlling an air volume of the fan so as to match a target air volume, wherein the control device
calculates an internal resistance of each of the battery cells, based on detection values of the voltage sensor and the current sensor, and
increases the target air volume as compared with when the internal resistances of the battery cells are all lower than a threshold value, when the internal resistance of any one battery cell of the battery cells exceeds the threshold value.

2. The battery system according to claim 1, wherein:
the battery pack is configured to store electric power for driving an electrified vehicle;
the battery system further includes
a temperature sensor for detecting an external temperature of at least one battery cell of the battery cells, and
a vehicle speed sensor for detecting a vehicle speed of the electrified vehicle; and the control device
decides the target air volume based on detection values of the temperature sensor and the vehicle speed sensor, when the internal resistances of the battery cells are all lower than the threshold value, and
increases the target air volume as compared with the target air volume that is decided based on the detection values of the temperature sensor and the vehicle speed sensor, when the internal resistance of any one battery cell of the battery cells exceeds the threshold value.

3. The battery system according to claim 2, wherein:
a plurality of modes are set regarding the fan, in which a relation between the vehicle speed of the electrified vehicle and the target air volume is different from one another, and the fan is configured to switch operation modes among the modes; and
when the internal resistance of any one battery cell of the battery cells exceeds the threshold value, the control device increases the target air volume for the same vehicle speed in at least one mode of the modes, as compared with when the internal resistances of the battery cells are all lower than the threshold value.

4. The battery system according to claim 2, wherein:
a plurality of modes are set regarding the fan, in which a relation between the vehicle speed of the electrified vehicle and the target air volume is different from one another, and the fan is configured to switch operation modes among the modes;
the control device is configured to switch the operation mode of the fan from a first mode to a second mode in which the target air volume for the same vehicle speed is greater, in accordance with the detection value of the temperature sensor reaching a switching temperature; and
the control device lowers the switching temperature when the internal resistance of any one battery cell of the battery cells exceeds the threshold value, as compared with when the internal resistances of the battery cells are all lower than the threshold value.

5. A cooling method for a battery pack, for cooling a battery pack including a plurality of battery cells, wherein:
the battery pack is configured to store electric power for driving an electrified vehicle, and includes
a voltage sensor that detects a voltage of each of the battery cells,
a current sensor that detects a current flowing through each of the battery cells,
a fan that cools the battery pack by feeding air to the battery pack, and
a temperature sensor for detecting an external temperature of at least one battery cell of the battery cells;
the electrified vehicle is provided with a vehicle speed sensor that detects a vehicle speed of the electrified vehicle; and
the cooling method includes
calculating an internal resistance of each of the battery cells based on detection values of the voltage sensor and the current sensor;
deciding a target air volume of the fan based on detection values of the temperature sensor and the vehicle speed sensor when the internal resistances of the battery cells are all lower than a threshold value;
increasing the target air volume as compared with the target air volume that is decided based on the detection values of the temperature sensor and the vehicle speed sensor, when the internal resistance of any one battery cell of the battery cells exceeds the threshold value, and
controlling an air volume of the fan so as to match the target air volume.
